(19) United States
(12) Patent Application Publication
(10) Pub. No.: US 2009/0159976 A1
(43) Pub. Date: Jun. 25, 2009

(54) INTEGRATED CIRCUIT AND METHOD FOR MAKING AN INTEGRATED CIRCUIT

(76) Inventors: Matthias Goldbach, Dresden (DE); Tobias Mono, Dresden (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 11/961,826

(22) Filed: Dec. 20, 2007

(51) Int. Cl. H01L 21/336; H01L 29/78

(52) U.S. Cl. 257/368; 438/275; 257/E29.255; 257/E21.409

(57) ABSTRACT

An integrated circuit comprises a dielectric layer located on a substrate and an electrode located on the dielectric layer. The electrode comprises a first metallic layer located on the dielectric layer and a second metallic layer. Moreover, a method of making an integrated circuit is described.

### BACKGROUND OF THE INVENTION

Components of integrated circuits frequently comprise a number or a stack of layers arranged on top of each other. The layers are formed by various processing steps including lithography, deposition, etching, polishing, etc. The particular processes are selected and tailored to meet desired performance requirements of the integrated circuits.

### BRIEF DESCRIPTION OF THE DRAWINGS

Various features of embodiments will become clear from the following description, taking in conjunction with the accompanying drawings. It is to be noted, however, that the accompanying drawings illustrate only typical embodiments and are, therefore, not to be considered limiting of the scope of the invention. The present invention may admit other equally effective variations.

FIGS. 1 to 5 illustrate schematic sectional views of a substrate for illustrating steps of a method for fabricating a transistor according to an embodiment;

FIGS. 6 and 7 illustrate schematic sectional views of a substrate comprising a transistor according to another embodiment.

FIGS. 8 to 11 illustrate schematic sectional views of a substrate for illustrating steps of a method for fabricating a transistor according to another embodiment.

FIG. 12 illustrates a further schematic sectional view of a substrate comprising a transistor according to another embodiment.

FIGS. 13 to 20 illustrate schematic sectional views of a substrate for illustrating steps of a method for fabricating a transistor according to another embodiment.

FIGS. 21 to 23 illustrate flow diagrams of different methods for making an integrated circuit according to an embodiment.

### DETAILED DESCRIPTION OF THE PREFERRED EMBODIMENT

The following embodiments described relate to an integrated circuit having a dielectric layer arranged on a substrate as well as an electrode arranged on said dielectric layer. The embodiments further relate to a method for fabricating such an integrated circuit.

Components of integrated circuits such as electrodes frequently comprise a number or a stack of layers arranged on top of each other. For example, a control electrode of a field effect transistor arranged on a dielectric layer, which is also referred to as the “gate”, may comprise a metallic layer arranged on the dielectric layer and a doped polysilicon layer arranged on the metallic layer. The work function of the gate electrode and thus the threshold voltage of the transistor is influenced by the metallic layer. The metallic layer is therefore also referred to as work function layer. The work function of the gate electrode may depend, amongst others, on the material and on the thickness of the metallic layer.

Polysilicon, e.g., allows for simple layer application and structuring. Contrary thereto, the problem of an interface layer formation occurs at the interface between the polysilicon layer and the metallic layer. It is possible that an oxide or a nitride is formed upon fabrication of the electrode. Such processes, which may occur even if the metallic layer is subjected to a cleaning step prior to applying the polysilicon, may particularly be ascribed to chemical reactions between the polysilicon layer and the metallic layer.

The belated forming of an additional interface layer between the polysilicon layer and the metallic layer may affect the properties and the function of the gate electrode. This results for example in the occurrence of an increased transitional resistance between the electrode layers, the electrode thereby exhibiting a high electrical resistance. The electrical resistance is further increased when the lateral dimensions of the electrode are reduced. Moreover, capacitive effects may occur at the interface between the polysilicon layer and the metallic layer.

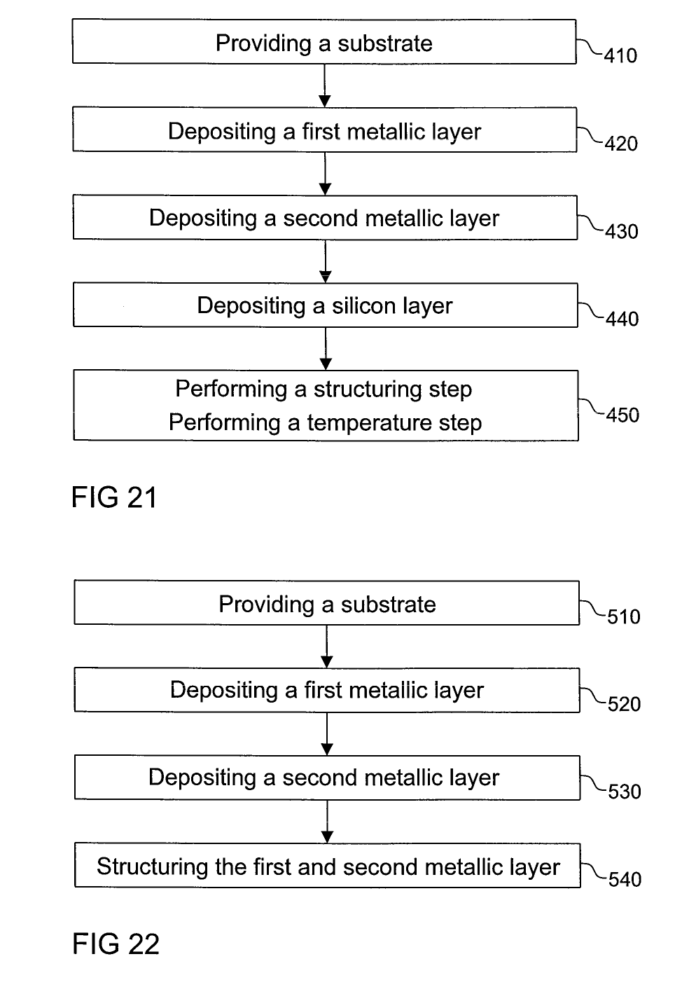

The subsequent embodiments relate to methods of making an integrated circuit comprising an electrode having several layers and to an integrated circuit, wherein formation of an interface layer between the provided electrode layers may be avoided. The methods are illustrated in the flow diagrams of FIGS. 21 to 23.

One embodiment of a method of making an integrated circuit is illustrated in FIG. 21. The method comprises providing a substrate having a dielectric layer (step 410), depositing a first metallic layer on the dielectric layer (step 420), depositing a second metallic layer on the first metallic layer having a metal appropriate for a silicidation (step 430), and depositing a silicon layer on the second metallic layer (step 440). The method further comprises performing a structuring step to form an electrode on the dielectric layer, and performing a temperature step, wherein at least a fraction of the second metallic layer is silicidized (step 450).

Another embodiment of a method of making an integrated circuit is illustrated in FIG. 22. The method comprises providing a substrate having a dielectric layer, the dielectric layer comprising a high-k-dielectric (step 510), depositing a first metallic layer on the dielectric layer (step 520), depositing a second metallic layer on the first metallic layer (step 530), and structuring the first and second metallic layer by means of a dry etching process to form an electrode on the dielectric layer (step 540).

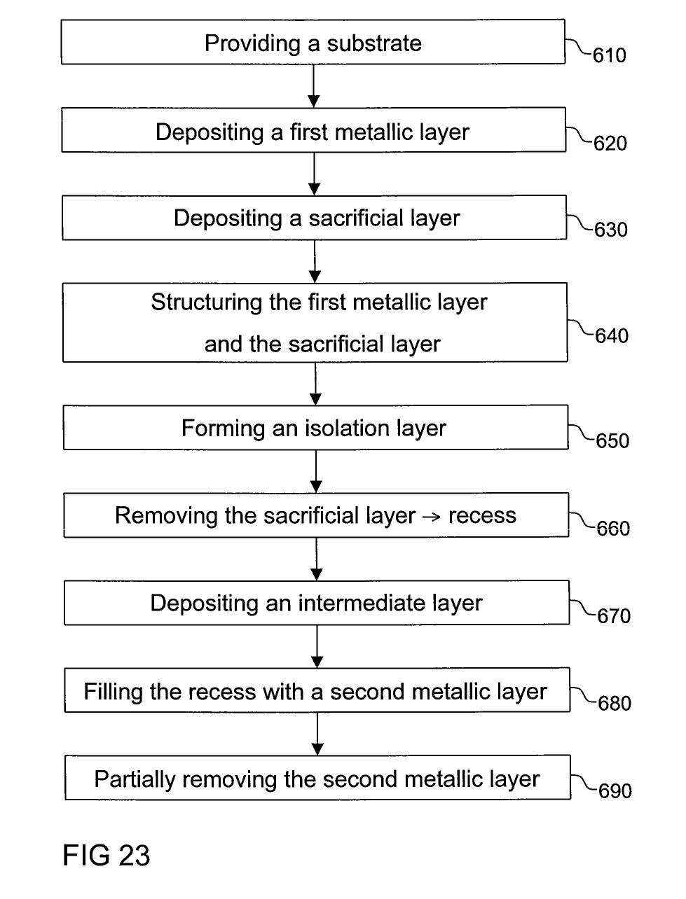

Another embodiment of a method of making an integrated circuit is illustrated in FIG. 23. The method comprises providing a substrate having a dielectric layer (step 610), depositing a first metallic layer on the dielectric layer (step 620), depositing a sacrificial layer on the first metallic layer (step 630), structuring the first metallic layer and the sacrificial layer to form a structure element (step 640), and forming an isolation layer on the substrate adjoining side walls of the structure element, wherein a surface of the sacrificial layer is uncovered (step 650). The method further comprises removing the sacrificial layer, thereby providing a recess and uncovering a surface of the first metallic layer (step 660), depositing an intermediate layer on the isolation layer and the uncovered surface of the first metallic layer in the recess (step 670), filling the recess with a second metallic layer (step 680), and partially removing the second metallic layer in such a manner that the second metallic layer remains solely inside the recess, and that an electrode comprising the first and second metallic layer is provided (step 690).

Another embodiment comprises an integrated circuit including a field effect transistor. The field effect transistor comprises a dielectric layer located on a substrate, a gate electrode located on the dielectric layer, and two doped substrate regions forming source/drain regions of the transistor. The dielectric layer comprises a high-k-dielectric. The electrode comprises a first metallic layer located on the dielectric layer and a second metallic layer.

Further embodiments are explained in conjunction with the following drawings. These embodiments relate to field effect transistors for an integrated circuit as well as to methods for their fabrication. The transistors comprise gate electrodes having a stack of different layers. The electrodes feature a low electrical resistance.

FIGS. 1 to 5 illustrate schematic lateral sectional views of a substrate 100 for illustrating steps of a method for fabricating a field effect transistor 190 having a gate electrode 180 according to an embodiment. The substrate 100, which comprises a semiconductor material such as silicon, may be a semiconductor wafer.

As illustrated in FIG. 1, the substrate 100 is provided with a dielectric layer 110 which forms the gate dielectric of the transistor 190 (shown in FIG. 5). In order to apply the dielectric layer 110 to the substrate 100, a deposition method such as the ALD method (atomic layer deposition) or the CVD method (chemical vapor deposition) may be carried out.

The dielectric layer 110 may comprise a high k dielectric. Potential high k dielectrics for the dielectric layer 110 include for example the materials HfSiO, HfSiON, HfO, BaTiO, SrZrO, SrTiO, LaO, DyO and AlO. The dielectric layer 110 may comprise the mentioned materials individually or in the form of material mixes. Alternatively, other materials may also be used for the dielectric layer 110, such as silicon dioxide and silicon oxynitride.

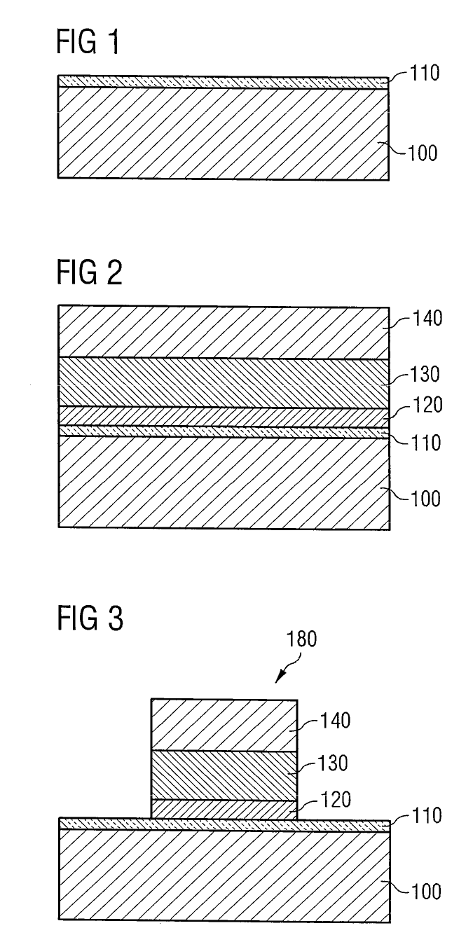

Thereafter, as illustrated in FIG. 2, a first metallic layer 120 is deposited on the dielectric layer 110, a second metallic layer 130 is deposited on the first metallic layer 120, and a silicon layer 140 is deposited on the second metallic layer 130 in a successive manner. The application of the layers 120, 130 and 140 may each be carried out by means of a deposition method such as the ALD and the CVD method, e.g. by means of a plasma-enhanced CVD (PECVD).

The work function of the gate 180 (shown in FIG. 5) and thus the threshold voltage of the transistor 190 (shown in FIG. 5) is influenced by the first metallic layer 120. Potential materials for the first metallic layer 120 are e.g. TaN, TaAlN, TaLaN, TaC, TaCN, TaCNO or TiN. The choice of these materials may depend on the transistor type of the transistor 190. For an n-channel field effect transistor, the materials TaC, TaN and TaLaN, and for a p-channel field effect transistor, the materials TaAlN, TaCN and TaCNO may for example be used.

The second metallic layer 130 comprises a metal appropriate for silicidation. Potential materials which may be applied are e.g. W, Ti, Co, Ni, Pt, Hf, Ta, Er, Yb, Pd or Re.

The silicon layer 140 may be applied to the second metallic layer 130 in the form of a polysilicon layer. Alternatively, the layer 140 may also comprise silicon in an amorphous form. By heating the substrate 100 or the layer 140, respectively, the amorphous silicon may subsequently be converted into polysilicon. Such a heating step for crystallizing the amorphous silicon may e.g. be carried out in a later stage of the method and may for example be carried out automatically within the framework of an effected temperature step after a fabrication of the electrode 180.

Furthermore, the silicon layer 140 may be doped in situ during deposition on the second metallic layer 130. Alternatively, the possibility exists that a doping of the silicon layer 140 be carried out by means of an ion implantation subsequent to depositing the silicon layer 140 on the second metallic layer 130 or in a later method stage.

Upon deposition of the first metallic layer 120 and prior to the deposition of the second metallic layer 130, one or more conditioning or cleaning steps may be carried out. In this way, oxides formed on the first metallic layer 120 and accumulated impurities may be removed, thus avoiding a formation of an interface layer between the first and the second metallic layer 120, 130 due to such contamination. As a means of use in such a conditioning step, e.g. diluted hydrofluoric acid may be used. Moreover, the use of further substances is conceivable which may e.g. comprise mixtures of nitrogen trifluoride and ammonia together with hydrofluoric acid. Correspondingly, one or more cleaning steps may also be carried out after depositing the second metallic layer 130 and prior to depositing the silicon layer 140.

In order to further avoid impurities, the deposition of the first metallic layer 120, the performing of the conditioning step(s), the deposition of the second metallic layer 130 and of the silicon layer 140 may be carried out in the same process device or process tool. In this manner, the substrate 100 may be continually subjected to a pressure and an atmosphere during and between these method steps, which is independent from the ambient atmosphere outside of the process device, so that undesired accumulation of impurities, which may be present in the ambient atmosphere outside of the process device, is avoided. For example, a vacuum may be maintained in the process device during and between the method steps.

In one embodiment, the first metallic layer 120, the second metallic layer 130 and the silicon layer 140 may be subsequently structured in order to form an electrode 180 serving as a gate and having substantially vertical side walls on the dielectric layer 110, as illustrated in FIG. 3. For this purpose, a dry etching process may for example be carried out. This is for example a reactive ion etching method (RIE) which achieves a high etching rate as well as a high degree of anisotropy. In order to define the lateral structure of the electrode 180, a corresponding area on the layer stack or on the silicon layer 140 may be covered by means of one or more suitable masking layers (not shown) prior to performing the etching process. As an example, a photo resist layer may be used which is applied to the silicon layer 140 and structured by performing a lithographic method. The application of a hard mask layer on the silicon layer 140 is also conceivable, the hard mask layer being structured in an additional etching process by means of a masking photo resist layer. During the structuring step for forming the electrode 180, respective uncovered areas of the layer stack are removed. As soon as the layer stack is structured and the dielectric layer 110 is uncovered, the etching process may be terminated. The masking layer or the masking layers, respectively, may be removed after formation of the electrode 180.

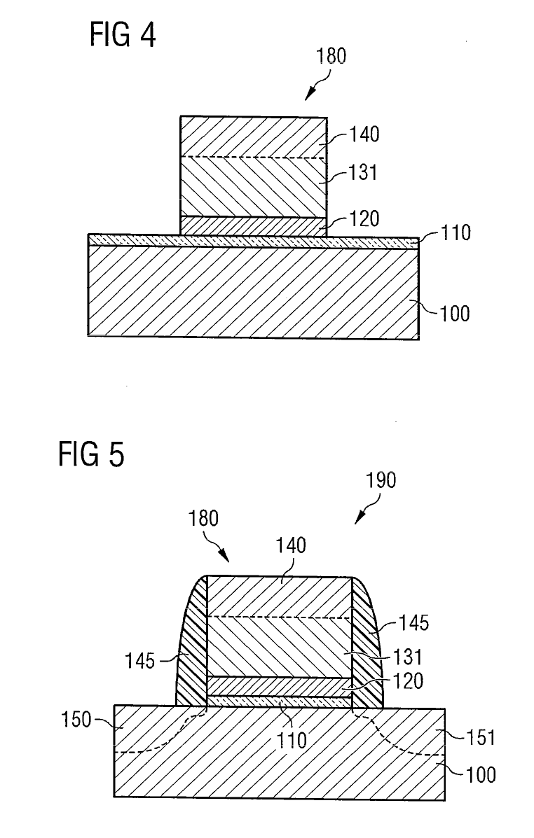

According to an embodiment, by performing a subsequent temperature step, at least a part of the second metallic layer 130 is silicidized due to a chemical reaction with the silicon of the silicon layer 140 applied thereon. Hereby, the second metallic layer 130 may also be completely silicidized so that a silicide layer 131 is formed between the first metallic layer 120 and the silicon layer 140, as illustrated in FIG. 4. The temperature step may be carried out at a temperature in a range between e.g. 250 to 1100° C.

Subsequently, according to an embodiment, further method steps may be carried out in order to provide the transistor 190 illustrated in FIG. 5 comprising the electrode 180 serving as a gate and two doped regions 150, 151 being separated from each other in the substrate 100 in a region below the electrode 180. The two doped regions 150, 151 serve as source and drain of the transistor 190.

The formation of the doped regions 150, 151 comprises performing an ion implantation process for introducing dopants into the substrate 100 and an annealing process in order to activate the implanted dopants. During the annealing process, the substrate 100 may be heated to a temperature of e.g. at least 800° C. and kept at this temperature for a duration of e.g. 10 minutes. The temporary heating of the substrate 100 to a temperature of e.g. 1000° C. is also possible.

In one embodiment, in order to implant dopants into the substrate 100 at a distance from the gate electrode 180, spacers 145 may be formed adjoining the side walls of the electrode 180 prior to performing the ion implantation process. In order to form the spacers 145, a layer also referred to as liner may be applied on the upper face of the substrate 100 or on the electrode 180, respectively, and subsequently a dry etching process may be carried out, so that the spacers 145 at the side walls of the electrode 180 remain. Silicon dioxide may e.g. be used as a material for the liner and thus for the spacers 145. In order to apply such a liner on the upper face of the substrate 100, a CVD method such as the so-called TEOS method involving tetraethyl orthosilicate (TEOS) as a precursor may be performed allowing for a conformal layer deposition.

In one embodiment, prior to forming the spacers 145, the uncovered region of the dielectric layer 110 not covered by the gate electrode 180 may for example be removed by means of a wet chemistry etching process so that the spacers 145 are formed directly on the surface of the substrate 100, as illustrated in FIG. 5. It is also possible to at first form the spacers 145 and to subsequently remove the uncovered region of the dielectric layer 110, thus arranging the spacers 145 on the dielectric layer 110 (not shown). By means of this procedure, the introduction of components of the dielectric layer 110 into the substrate 100 which might be caused by the ion implantation process and which might affect the properties of the doped regions 150, 151, can be avoided.

According to another embodiment, instead of a single ion implantation process for introducing dopants into the substrate 100, an ion implantation may be carried out several times. For example, (prior to or after the removal of the dielectric layer 110 in uncovered areas) first spacers may be formed adjacent to side walls of the gate 180 and dopants may be implanted relatively close to the surface of the substrate 100 in a first ion implantation process, which is also referred to as LDD doping (lightly doped drain). Furthermore, second spacers may be formed adjacent to the first spacers and dopants may be introduced deeper into the substrate 100 in a second ion implantation process. Upon activating the implanted dopants by performing an annealing process subsequently to each ion implanting process or by performing a single annealing process after the two implanting processes, doped regions 150, 151 serving as source and drain may be provided in the substrate 100. Such a multi-stage procedure is indicated by the shape of the doped regions 150, 151 shown in FIG. 5. Thus, the illustrated spacers 145 may be composed of the above described first and second spacers. Furthermore, an additional implantation process may be carried out in which dopants may be introduced at a predefined angle with respect to the side walls of the gate 180 laterally below the gate 180. This process, which is also referred to as halo implantation, allows for improving the short channel behavior of the transistor 190.

In the case of a substrate 100 comprising silicon, it is furthermore possible to perform a so-called salicide process (salicide=self aligned silicide), in order to selectively silicidize the substrate 100 in the area of the doped regions 150, 151. During the salicide process, a metallic layer comprising e.g. Ti, Co or Ni is applied to the substrate 100. A temperature step is carried out as well, by means of which the substrate 100 is silicidized. In order to selectively achieve silicidation in the area of the doped regions 150, 151, the substrate 100 as well as the electrode 180 may be covered at corresponding locations by means of masking layers prior to application of the metallic layer (not shown).

The electrode 180 of the transistor 190 features a relatively low electrical resistance. This may be caused by the fact that due to the arrangement of the silicide layer 131 on the first metallic layer 120 a later formation of an interface layer at the interface between these two layers 120, 131 affecting the function of the electrode 180, which occurs along with an increased transitional resistance between the layers 120, 131, is avoided with a high reliability. Moreover, interface capacitive effects in the electrode 180 during operation of the transistor 190 may be reduced or eliminated. Such properties may also be achieved by means of an electrode in which only a part of the second metallic layer 130 is silicidized (not shown).

Apart from the above-mentioned method for fabricating a transistor with a gate electrode comprising a silicide layer, variations of the described method are conceivable. For example, the temperature step for silicidizing the second metallic layer 130 may be carried out after forming the spacers 145 and performing one (or several) ion implantation processe(s). Such a temperature step for silicidation may be employed simultaneously in order to activate dopants introduced into the substrate 100.

Moreover, a silicidation of the second metallic layer 130 may alternatively be performed already prior to the structuring step for forming the electrode 180 (not shown). The structuring step may be performed as well by means of a dry etching process, e.g. a reactive ion etch.

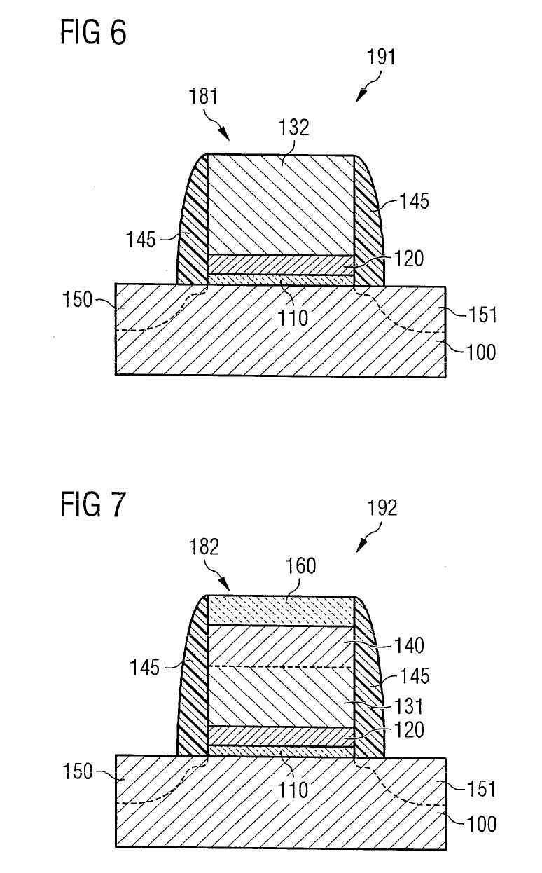

Furthermore, the silicon layer 140 may be fully consumed during silicidation (carried out prior to or after the structuring step) of the second metallic layer 130. For reasons of illustration, FIG. 6 shows a further embodiment of a transistor 191 comprising a gate electrode 181. The gate electrode 181 comprises a first metallic layer 120 and a silicide layer 132, wherein no unreacted silicon is left on the silicide layer 132.

Furthermore, additional layers may be provided in a gate electrode comprising a silicide layer. In this connection, FIG. 7 illustrates a further embodiment of a transistor 192 having a gate electrode 182 in which, contrary to the gate electrode 180 of the transistor 190 of FIG. 5 a further layer 160 is arranged on the silicon layer 140. This further layer 160 is e.g. deposited on the silicon layer 140 prior to the structuring step for forming the electrode 182. It is also conceivable to form several layers on the silicon layer 140 (not shown). As a material for a further layer e.g. metals such as titanium and tungsten as well as a silicide may be applied. The forming of additional layers is correspondingly possible for transistors having gate electrodes, in which a silicon layer is completely consumed during silicidation (not shown).

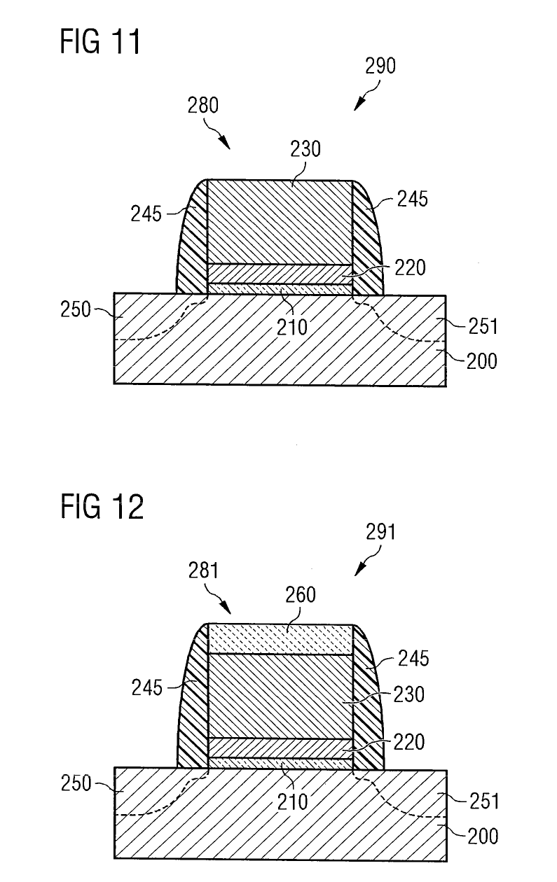

The subsequent FIGS. 8 to 11 illustrate schematic lateral sectional views of a substrate 200 for illustrating steps of a method for fabricating a field effect transistor 290 (shown in FIG. 11) comprising a gate electrode 280 (shown in FIG. 11) according to a further embodiment. The substrate 200 which is e.g. a wafer comprises a semiconductor material such as e.g. silicon.

The substrate 200 is provided with a dielectric layer 210, as illustrated in FIG. 8, which forms the gate dielectric of the transistor 290. The application of the dielectric layer 210 onto the substrate 200 may be carried out by means of a deposition method such as an ALD or a CVD method. The dielectric layer 210 comprises a high k dielectric. Potential materials for high k dielectrics are e.g. HfSiO, HfSiON, HfO, BaTiO, SrZrO, SrTiO, LaO, DyO and AlO. The dielectric layer 110 may also comprise mixtures of the mentioned materials, or mixtures with SiO and SiON.

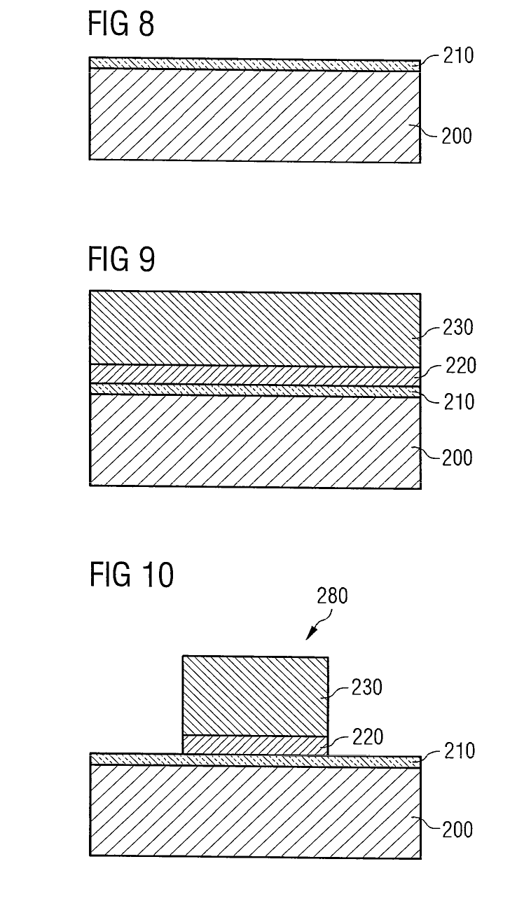

Subsequent thereto, a first metallic layer 220 may be deposited on the dielectric layer 210, and a second metallic layer 230 may be deposited on the first metallic layer 220 in a successive manner, as illustrated in FIG. 9. The application of the layers 220, 230 may respectively be carried out by means of a deposition method such as the ALD or the CVD process.

The threshold voltage of the transistor 290 may be influenced by the first metallic layer 220, which e.g. comprises one of the materials TaN, TaAlN, TaLaN, TaC, TaCN, TaCNO or TiN. The choice of the mentioned materials may depend on the transistor type of the transistor 290. In the case of an n-channel field effect transistor, e.g. the materials TaC, TaN and TaLaN, and in the case of a p-channel field effect transistor, the materials TaAlN, TaCN and TaCNO may be applied.

The second metallic layer 230 comprises a metal having a high thermal stability and which may be reliably structured in a dry etching process, allowing for a simple and uncomplicated fabrication of the transistor 290. The thermal stability may be significant with regard to subsequent method steps in which high temperatures occur. Thereby, an annealing process used during fabrication of doped regions may be considered, in which temperatures of e.g. 800° C. and more may occur. Further method steps involving high temperatures may be additionally performed deposition processes. A metal which is for example used for the second metallic layer 230 and to which these properties apply is tungsten.

Upon deposition of the first metallic layer 220 and prior to the deposition of the second metallic layer 230, one or more conditioning or cleaning steps may be carried out in order to remove oxides formed on the first metallic layer 220 or accumulated impurities. Consequently, the formation of an interface layer between the two layers 220, 230 may be avoided due to such impurities. Means of use in such a conditioning step are e.g. diluted hydrofluoric acid or mixtures of hydrofluoric acid and nitrogen trifluoride or ammonia.

Moreover, the deposition of the first metallic layer 220, the performing of the conditioning step(s) as well as the deposition of the second metallic layer 230 may be carried out in the same process device. In this way, the substrate 200 may be continually subjected to a pressure and an atmosphere during and between these method steps, which may be independent from the ambient atmosphere outside of the process device, thus avoiding the accumulation of impurities which may be present in the ambient atmosphere outside of the process device.

Subsequently, the first and second metallic layers 220, 230 are structured by means of a dry etching process in order to form a gate electrode 280 having substantially vertical side walls on the dielectric layer 210, as illustrated in FIG. 10. In order to carry out the structuring of the first and the second metallic layer 220, 230 with a high etching rate and a high degree of anisotropy, reactive ion etching may be performed.

Prior to carrying out the etching process, a specific area of the layer stack or of the second metallic layer 230, respectively, which defines the lateral structure of the electrode 280, may be covered with one or more suitable masking layers (not shown). Hereby, e.g. a photo resist layer structured by means of a lithographic process or a hard mask layer structured in an additional etching process may be employed. In the course of the dry etching process for forming the electrode 280, respective uncovered areas of the layer stack are removed. As soon as the dielectric layer 210 is uncovered, the etching process may be terminated. The masking layer or the masking layers, respectively, may be removed after formation of the electrode 280.

The electrode 280 formed in such a way comprises a relatively low electrical resistance. This property is based on a low transitional resistance between the two metallic layers 220, 230, since a later formation of an interface layer at the interface between the layers 220, 230 is avoided with high reliability. For this reason, as well, no interface capacitive effects occur in the electrode 280 during operation of the transistor 290.

Subsequently, further method steps may be performed in order to provide the transistor 290 shown in FIG. 11 with the gate electrode 280 and two separate doped regions 250, 251 in the substrate 200 in a region below the electrode 280. In order to form the doped regions 250, 251 serving as source and drain of the transistor 290, an ion implantation process for implanting dopants into the substrate 200 and an annealing process for activating the dopants may be carried out. In the annealing process, the substrate 200 may be heated to a temperature of e.g. at least 800° C. and kept at this temperature for a duration of e.g. ten minutes. Alternatively, temporary heating of the substrate 100 to a temperature of e.g. 1000° C. is possible.

Prior to performing the ion implantation, spacers 245 may be formed adjacent to side walls of the electrode 280 in order to introduce dopants into the substrate 200 in a laterally displaced manner with regard to the side walls of the electrode 280. Moreover, an uncovered fraction of the dielectric layer 210 may be removed (before or after forming the spacers 245) by means of a wet chemistry etching process. As a result, an introduction of components of the dielectric layer 210 into the substrate 200 which might be caused by the ion implantation, due to which properties of the doped regions 250, 251 may be affected, may be avoided (in FIG. 11, the variant of removing the uncovered fraction of the layer 210 prior to forming the spacers 245 is depicted).

The formation of the doped regions 250, 251 may furthermore be performed in several stages by forming first and second spacers and by carrying out a first and a second ion implantation. Such a multi-stage procedure is indicated by the shape of the doped regions 250, 251 shown in FIG. 11. Furthermore, a halo implantation doping and/or a salicide process may be carried out. With regard to these method steps as well as to further details concerning e.g. the formation of the spacers, reference is made to the above information with regard to the method described in conjunction with FIGS. 1 to 5.

Apart from the above mentioned method, further variations of the described method are conceivable. With regard thereto, FIG. 12 illustrates an alternative embodiment of a transistor 291 having a gate electrode 281 which comprises a first and a second metallic layer 220, 230 and, contrary to the gate electrode 280 of the transistor 290 of FIG. 11, additionally comprises a further layer 260 arranged on the second metallic layer 230. The layer 260 which e.g. comprises a silicide or a metal such as titanium or tungsten may for example be applied prior to the structuring step for forming the electrode 281 on the second metallic layer 230. It is also possible to form several layers on the second metallic layer 230 (not shown).

The following FIGS. 13 to 20 illustrate schematic lateral sectional views of a substrate 300 for illustrating steps of a method for fabricating a field effect transistor 390 having a gate electrode 380 according to a further embodiment. The substrate 300, which comprises a semiconductor material such as silicon, is e.g. a wafer.

The substrate 300 is provided with a dielectric layer 310, as shown in FIG. 13, the dielectric layer 310 forming the gate dielectric of the transistor 390. In order to apply the dielectric layer 310 onto the substrate 300, a deposition method such as an ALD or a CVD method may be carried out. The dielectric layer 310 may comprise a high k dielectric. Potential high k dielectrics for the layer 310 are e.g. the materials HfSiO, HfSiON, HfO, BaTiO, SrZrO, SrTiO, LaO, DyO and AlO. The dielectric layer 110 may comprise the mentioned materials individually or in the form of material mixes. Alternatively, other materials may also be used for the dielectric layer 110, such as silicon dioxide and silicon oxynitride.

In the following, a first metallic layer 320 may be deposited on the dielectric layer 310, and a sacrificial layer 330 may be deposited on the first metallic layer 320 in a successive manner, as shown in FIG. 14. The application of the layers 320, 330 may respectively be carried out by means of a deposition method such as the ALD or the CVD process. The first metallic layer 320, by means of which the threshold voltage of the transistor 390 is influenced, for example comprises one of the materials TaN, TaAlN, TaLaN, TaC, TaCN, TaCNO or TiN. The choice of the mentioned materials may depend on the transistor type of the transistor 390. For an n-channel field effect transistor, e.g. the materials TaC, TaN and TaLaN, and for a p-channel field effect transistor, the materials TaAlN, TaCN and TaCNO may be considered. The sacrificial layer 330 may e.g. comprise silicon or polysilicon, respectively.

Upon deposition of the first metallic layer 320 and prior to the deposition of the sacrificial layer 330 one or more conditioning or cleaning steps may be carried out. In this way, it is possible to remove oxides formed on the first metallic layer 320 or accumulated impurities prior to applying the sacrificial layer 330, so that the formation of an interface layer between the two layers 320, 330 is avoided. Means of use in such a conditioning step are for example a diluted hydrofluoric acid or mixtures of hydrofluoric acid and nitrogen trifluoride or ammonia.

Moreover, the deposition of the first metallic layer 320, the performing of the conditioning step(s) and the deposition of the sacrificial layer 330 may be carried out in the same process device. In this way, the substrate 300 may be continually subjected to a pressure and an atmosphere during and between these method steps, which is independent from the ambient atmosphere outside of the process device, thus avoiding the accumulation of impurities which may be present in the ambient atmosphere outside of the process device.

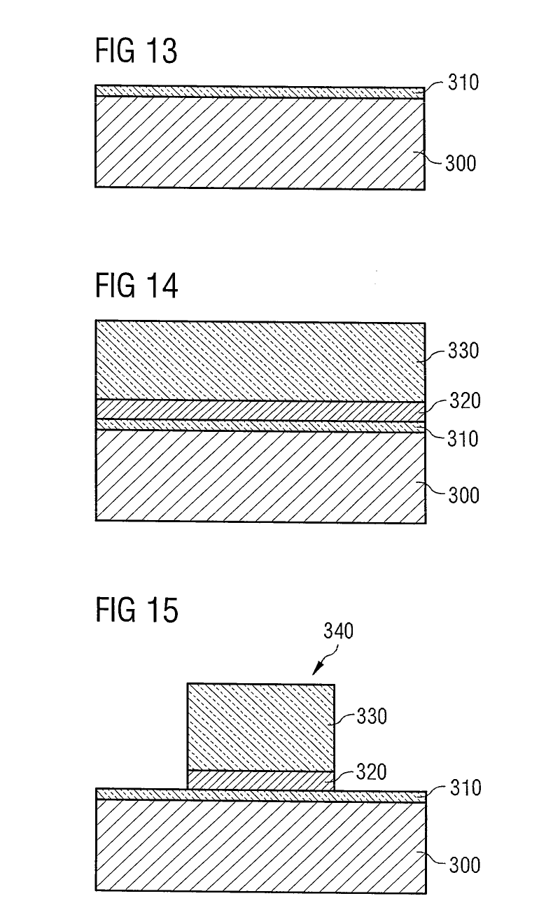

Subsequently, the sacrificial layer 330 and the first metallic layer 320 are structured, thereby forming a structure element 340 having substantially vertical side walls on the dielectric layer 310, as illustrated in FIG. 15. The structuring of the two layers 320, 330 is for example carried out by means of a dry etching process, such as reactive ion etching. Prior to carrying out the structuring step, a specific area of the layer stack or of the sacrificial layer 330, respectively, which defines the lateral structure of the structure element 340, may be covered with one or several suitable masking layers (not depicted). For this purpose, e.g. a photoresist layer structured by means of a lithographic method or also a hard mask layer structured in an additional etching process may be used. In the course of the etching process, respective uncovered areas of the layer stack are removed. As soon as the dielectric layer 310 is uncovered, the etching process may be terminated. The masking layer or the masking layers, respectively, may be removed upon forming of the structure element 340.

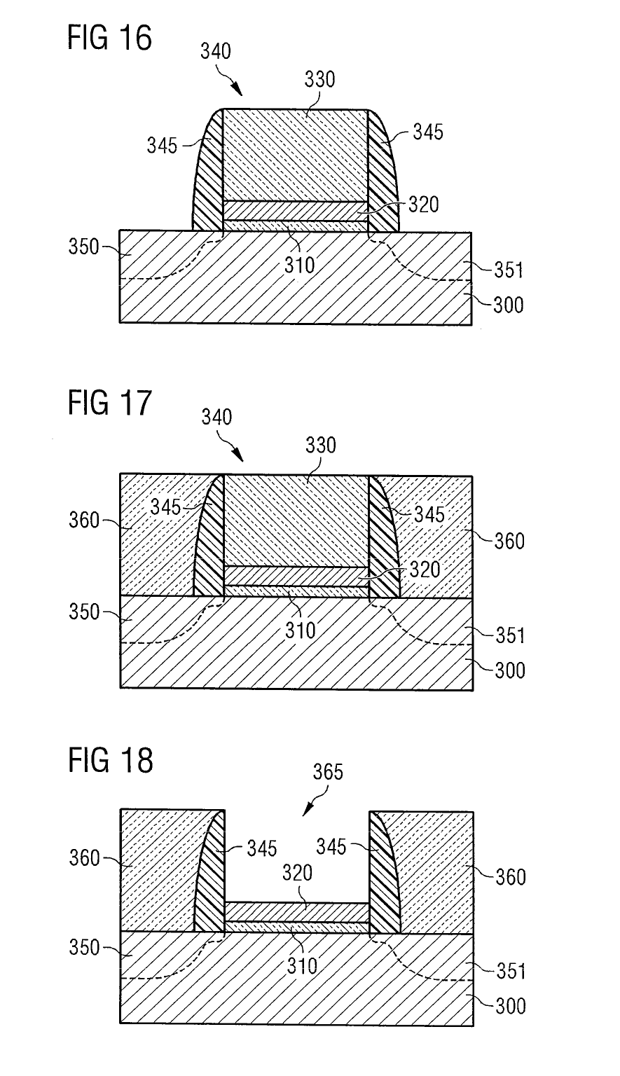

In on embodiment, subsequent to the formation of the structure element 340, two separate doped regions 350, 351 may be formed in the substrate 300 in a region below the structure element 340, as illustrated in FIG. 16. In order to form the doped regions 350, 351, which serve as source and drain of the transistor 390, an ion implantation process for introducing dopants into the substrate 300 and an annealing process for activating the dopants may be carried out. Before carrying out the ion implantation, spacers 345 may be formed adjoining the side walls of the structure element 340, in order to implant the dopants into the substrate 300 in a laterally displaced manner with regard to the structure element 340. Moreover, an uncovered fraction of the dielectric layer 310 may be removed (before or after forming the spacers 345) e.g. by means of a wet chemistry etching process. In this way, an introduction of components of the dielectric layer 310 into the substrate 300 which might be caused by the ion implantation, due to which properties of the doped regions 350, 351 may be affected, may be avoided (in FIG. 16, the variant of removing the uncovered fraction of the layer 310 prior to forming the spacers 345 is depicted).

The formation of the doped regions 350, 351 may also be carried out in several stages by forming first and second spacers and by performing a first and a second ion implantation. Such a procedure is indicated by the shape of the doped regions 350, 351 shown in FIG. 16. Additionally, a halo implantation doping and/or a salicide process may also be carried out. With regard to these method steps as well as to further details which e.g. concern the temperatures applied in an annealing process and the formation of the spacers, reference is made to the above information with regard to the method described in conjunction with FIGS. 1 to 5.

After forming the doped regions 350, 351, a further dielectric layer 360 may be formed on the substrate 300 adjoining the spacers 345, as shown in FIG. 17. Thereby, the surface of the sacrificial layer 330 is uncovered. In order to form such a dielectric layer 360, a corresponding dielectric material may be deposited on the upper face of the substrate 300 and on the spacers 345 and the sacrificial layer 330, respectively, and a polishing process such as a CMP process (chemical-mechanical polishing) may subsequently be carried out, so that the dielectric material above the upper edge of the spacers 345 or above the sacrificial layer 330 is removed and the surface of the sacrificial layer is uncovered.

As a material for the dielectric layer 360, for example boron phosphorus silicate glass (BPSG) may be considered. It is also possible to use a so-called spin on dielectric (SOD) which is deposited on the upper face of the substrate 300 while the substrate 300 rotates. Furthermore, silicon dioxide may be used for the dielectric layer 360, which may be deposited on the upper face of the substrate 300 by performing a TEOS process in which tetraethyl orthosilicate (TEOS) is used as precursor material.

In order to stop the polishing process carried out for uncovering the surface of the sacrificial layer 330 in a defined manner, a polishing stop layer may be deposited on the upper face of the substrate 300 (not shown) prior to applying the dielectric material for the layer 360—for instance prior to forming second spacers. The polishing stop layer may for example comprise silicon nitride. If the fraction of the polishing stop layer above the sacrificial layer 330 is not removed by the polishing process, the polishing stop layer may subsequently be removed by means of a wet chemistry etching process, e.g. by means of a phosphorous acid or HFEG (HF: hydrofluoric acid, EG: ethylene glycol).

In a subsequent method step, the sacrificial layer 330 is removed so that a recess 365 is provided between the spacers 345 as illustrated in FIG. 18, which uncovers a surface of the first metallic layer 320. In order to selectively remove the sacrificial layer 330, a wet chemistry etching process may be carried out. An example is a wet chemistry etch on the basis of ammonia.

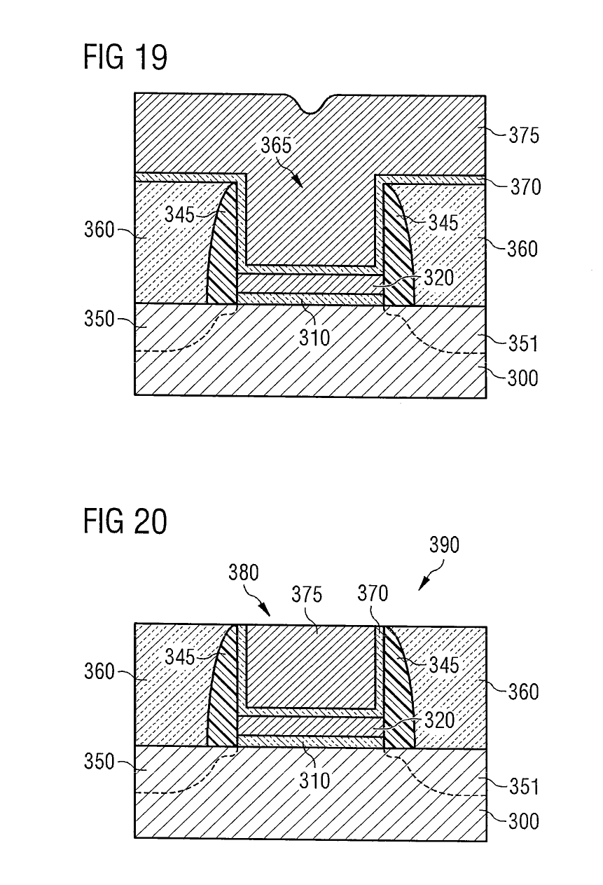

Subsequent to the formation of the recess 365, an intermediate layer 370 is deposited on the dielectric layer 360, the spacers 345 and the uncovered surface of the first metallic layer 320 in the recess 365, as illustrated in FIG. 19. The intermediate layer 370 acts as a diffusion barrier in the transistor 390 (shown in FIG. 20), as will be described below. In order to reliably avoid undesired diffusion processes, the intermediate layer 370 comprises e.g. TaN. In order to deposit the intermediate layer 370, a CVD process, e.g. a pulsed or a plasma-enhanced CVD process may be performed.

Moreover, a second metallic layer 375 may be deposited on the intermediate layer 370 in a large-area manner, as illustrated in FIG. 19, thus filling the recess 365. In an embodiment, the second metallic layer 375 comprises one of the highly conductive metals Cu, Au, Ag or Al or a combination of the mentioned metals. The deposition of the second metallic layer 375 while filling the recess 365 is for example carried out by means of an electroplating process.

In the run-up of such an electroplating process, a thin layer of a further material and a seed layer of the metal to be deposited by electro-plating may be applied on the intermediate layer 370 (not shown). The layer of the further material, for which Ta may be considered in the case of an intermediate layer 370 comprising TaN, may serve to determine a crystalline phase of the seed layer. The deposition of the layer of the further material and of the seed layer may each be carried out by means of a plasma-enhanced CVD process. Subsequent to these method steps, the electroplating process for forming the second metallic layer 375 may be carried out.

Upon performing the electroplating process, the second metallic layer 375 may be partially removed, as illustrated in FIG. 20, so that the second metallic layer 375 remains within the recess 365 (shown in FIG. 19). This method step may be carried out by means of a polishing process, such as a CMP process. In this way, an electrode 380 comprising the first and the second metallic layer 320, 375 may be formed, thus substantially finishing the transistor 390. During polishing, the intermediate layer 370 may be removed in areas above the dielectric layer 360 and the spacers 345, as illustrated in FIG. 20.

The electrode 380 fabricated by means of the method described in conjunction with FIGS. 13 and 20 comprises a relatively low electrical resistance since a formation of an interface layer between the provided electrode layers and an associated increased transitional resistance are avoided. For this reason, as well, the electrode 380 is not affected by capacitive effects during operation of the transistor 390. In particular, the first and the second metallic layer 320, 375 may be separated from each other by the intermediate layer 370, thus suppressing any chemical reactions between the first and the second metallic layer 320, 375 which may occur.

Moreover, in the electrode 380 of the transistor 390 the second metallic layer 375 is partly enclosed or encapsulated by the intermediate layer 370, wherein a surface of the second metallic layer 375 is uncovered. Due to the encapsulation, materials or metals with a critical diffusion behavior may be used for the second metallic layer 375. This applies for example to the above-mentioned metals Cu, Au and Ag. The enclosing intermediate layer 370 avoids a diffusion of material of the second metallic layer 375 in undesirable areas, e.g. into the substrate, and an associated impact on the transistor 390.

In the method, the spatial structure of the second metallic layer 375 in the electrode 380 is defined by introducing the second metallic layer 375 into the recess 365. The method thus allows for the use of materials or metals for the second metallic layer 375, which may be difficult to structure by means of an anisotropic etching process such as a dry etching process. This is e.g. the case for the above mentioned metals Cu, Au and Ag. Alternative metals for the second metallic layer 375 are e.g. Ti and W.

According to the described method, the formation of the second metallic layer 375 may be carried out after forming the doped regions 350, 351 and after an annealing process performed at a high temperature. Therefore, materials may be used for the second metallic layer 375 which are thermally unstable in such an annealing process.

In order to make sure that the second metallic layer 375 is completely removed outside of the recess 365 and no undesired diffusions occur on the substrate 300 for that reason, additional method steps may be carried out. For example, the substrate 300 may be subjected to an extensive wet chemistry etch in the course of which the second metallic layer 375 is etched back to a percentage even in recess 365. Since this involves the danger that also the intermediate layer 370 is etched off in an area between the spacers 345 and the second metallic layer 375, thus affecting the encapsulation of the second metallic layer 375, a renewed deposition of the material of the intermediate layer 370 may be carried out in a further step. Subsequently, a selective back-etching may be carried out in order to again uncover a surface of the second metallic layer 375. In this manner, a possibly affected or incomplete encapsulation of the second metallic layer 375 may be reproduced.

The embodiments described in conjunction with the drawings are examples. Moreover, further implementations may be realized which comprise further modifications. In the course of a structuring step for forming a gate electrode or a structure element, for example, a dielectric layer acting as a gate dielectric may be structured as well without performing an additional wet chemistry etch.

Moreover, the indicated materials or metals for the various layers in the methods or transistors, respectively, are examples and not limiting. Instead of the given materials or metals, other materials may be employed. Concerning further particulars, e.g. with respect to performing conditioning steps and wet chemistry etches, the mentioned materials are to be considered exemplary and not limiting, as well, and may be replaced by other materials. This also applies to temperature data given with respect to e.g. annealing processes.

The methods may also comprise further method steps than those described. In the run-up to an etching process for fabricating spacers, for example, additional deposition and lithographic processes may be performed, in order to mask an upper face of a substrate in a selected area with respect to the etching process, such as e.g. an area comprising memory cells.

Moreover, the described method steps for forming an electrode are not limited to the fabrication of a field effect transistor. The indicated method steps may be correspondingly carried out for forming structure elements or electrodes comprising several layers within the framework of fabricating other electric or electronic components.

The preceding description describes examples of embodiments of the invention. The features disclosed therein and the claims and the drawings can, therefore, be useful for realizing the invention in its various embodiments, both individually and in any combination. While the foregoing is directed to embodiments of the invention, other and further embodiments of this invention may be devised without departing from the basic scope of the invention, the scope of the present invention being determined by the claims that follow.

What is claimed is:

1. A method of making an integrated circuit comprising:
providing a substrate having a dielectric layer;
depositing a first metallic layer on the dielectric layer;
depositing a second metallic layer on the first metallic layer comprising a metal appropriate for a silicidation;
depositing a silicon layer on the second metallic layer;
performing a structuring step to form an electrode on the dielectric layer; and
performing a temperature step, wherein at least a fraction of the second metallic layer is silicidized.

2. The method according to claim 1, wherein the second metallic layer is fully silicidized.

3. The method according to claim 1, wherein the silicon layer is fully consumed in the silicidation of the second metallic layer.

4. The method according to claim 1, wherein the second metallic layer comprises one of the following metals: W, Ti, Co, Ni, Pt, Hf, Ta, Er, Yb, Pd, Re.

5. The method according to claim 1, wherein the first metallic layer comprises one of the following materials:
TaN, TaAlN, TaLaN, TaC, TaCN, TaCNO, TiN.

6. The method according to claim 1, wherein the dielectric layer comprises a high-k-dielectric.

7. The method according to claim 1, wherein the dielectric layer comprises one of the following materials: SiO, SiON, HfSiO, HfSiON, HfO, BaTiO, SrZrO, SrTiO, LaO, DyO, AlO.

8. The method according to claim 1, wherein performing the structuring step to form the electrode is carried out by means of a dry etching process.

9. The method according to claim 1, wherein a conditioning step is carried out after depositing the first metallic layer and before depositing the second metallic layer.

10. The method according to claim 9, wherein depositing the first metallic layer, carrying out the conditioning step, depositing the second metallic layer and depositing the silicon layer is performed within the same process device.

11. A method of making an integrated circuit comprising:
providing a substrate having a dielectric layer, the dielectric layer comprising a high-k-dielectric;
depositing a first metallic layer on the dielectric layer;
depositing a second metallic layer on the first metallic layer; and
structuring the first and second metallic layer by means of a dry etching process to form an electrode on the dielectric layer.

12. The method according to claim 11, further comprising forming two doped regions being separated from each other in the substrate in a region below the electrode by means of an ion implantation process and an annealing process, wherein the annealing process is carried out at a temperature of at least 800° C.

13. The method according to claim 11, wherein the second metallic layer comprises tungsten.

14. The method according to claim 11, wherein the first metallic layer comprises one of the following materials:
TaN, TaAlN, TaLaN, TaC, TaCN, TaCNO, TiN.

15. The method according to claim 11, wherein the dielectric layer comprises one of the following materials: SiO, SiON, HfSiO, HfSiON, HfO, BaTiO, SrZrO, SrTiO, LaO, DyO, AlO.

16. The method according to claim 11, wherein structuring the first and second metallic layer is carried out by means of a reactive ion etching process.

17. The method according to claim 11, wherein a conditioning step is carried out after depositing the first metallic layer and before depositing the second metallic layer.

18. The method according to claim 17, wherein depositing the first metallic layer, carrying out the conditioning step and depositing the second metallic layer is performed within the same process device.

19. A method of making an integrated circuit comprising:
providing a substrate having a dielectric layer;
depositing a first metallic layer on the dielectric layer;
depositing a sacrificial layer on the first metallic layer;
structuring the first metallic layer and the sacrificial layer to form a structure element;
forming an isolation layer on the substrate adjoining side walls of the structure element, wherein a surface of the sacrificial layer is uncovered;
removing the sacrificial layer, thereby providing a recess and uncovering a surface of the first metallic layer;
depositing an intermediate layer on the isolation layer and the uncovered surface of the first metallic layer in the recess;
filling the recess with a second metallic layer; and
partially removing the second metallic layer in such a manner that the second metallic layer remains solely inside the recess, and that an electrode comprising the first and second metallic layer is provided.

20. The method according to claim 19, wherein the second metallic layer comprises one of the following metals: Cu, Au, Ag, Al, Ti, W.

21. The method according to claim 19, wherein the intermediate layer comprises TaN.

22. The method according to claim 19, wherein the sacrificial layer comprises silicon.

23. The method according to claim 19, wherein filling the recess with the second metallic layer is carried out by means of an electroplating process.

24. The method according to claim 19, wherein partially removing the second metallic layer is carried out by means of a polishing process.

25. The method according to claim 19, wherein the first metallic layer comprises one of the following materials:
TaN, TaAlN, TaLaN, TaC, TaCN, TaCNO, TiN.

26. The method according to claim 19, wherein the dielectric layer comprises a high-k-dielectric.

27. The method according to claim 19, wherein the dielectric layer comprises one of the following materials: SiO, SiON, HfSiO, HfSiON, HfO, BaTiO, SrZrO, SrTiO, LaO, DyO, AlO.

28. The method according to claim 19, wherein structuring the first metallic layer and the sacrificial layer is carried out by means of a dry etching process.

29. The method according to claim 19, wherein forming the isolation layer comprises:
forming spacers on the substrate adjoining the side walls of the structure element; and
forming a further dielectric layer on the substrate adjoining the spacers.

30. The method according to claim 19, wherein a conditioning step is carried out after depositing the first metallic layer and before depositing the sacrificial layer.

31. The method according to claim 30, wherein depositing the first metallic layer, carrying out the conditioning step and depositing the sacrificial layer is performed within the same process device.

32. An integrated circuit including a field effect transistor comprising:
a dielectric layer located on a substrate, the dielectric layer comprising a high-k-dielectric;
a gate electrode located on the dielectric layer, the gate electrode comprising a first metallic layer located on the dielectric layer and a second metallic layer; and
two doped substrate regions forming source/drain regions of the transistor.

33. The integrated circuit according to claim 32, wherein the second metallic layer is located on the first metallic layer and comprises a silicide.

34. The integrated circuit according to claim 33, wherein the silicide comprises one of the following metals: W, Ti, Co, Ni, Pt, Hf, Ta, Er, Yb, Pd, Re.

35. The integrated circuit according to claim 32, wherein the second metallic layer is located on the first metallic layer and comprises tungsten.

36. The integrated circuit according to claim 32, further comprising an intermediate layer which separates the first and second metallic layer from each other.

37. The integrated circuit according to claim 36, wherein the second metallic layer comprises one of the following metals: Cu, Au, Ag, Al, Ti, W.

38. The integrated circuit according to claim 36, wherein the intermediate layer comprises TaN.

39. The integrated circuit according to claim 32, wherein the first metallic layer comprises one of the following materials: TaN, TaAlN, TaLaN, TaC, TaCN, TaCNO, TiN.

40. The integrated circuit according to claim 32, wherein the dielectric layer comprises one of the following materials: SiO, SiON, HfSiO, HfSiON, HfO, BaTiO, SrZrO, SrTiO, LaO, DyO, AlO.
